(19) United States
(12) Patent Application Publication
(10) Pub. No.: US 2014/0311899 A1
(43) Pub. Date: Oct. 23, 2014

(54) Ferromagnetic Material Sputtering Target

(71) Applicant: JX Nippon Mining & Metals Corporation, Tokyo (JP)

(72) Inventor: Yuki Ikeda, Ibaraki (JP)

(21) Appl. No.: 14/354,953

(22) PCT Filed: Jan. 21, 2013
(86) PCT No.: PCT/JP2013/051095

§ 371 Date: Apr. 29, 2014

(30) Foreign Application Priority Data
Jan. 25, 2012 (JP) 2012-012546

(51) Int. Cl. H01J 37/34

(52) U.S. Cl. CPC H01J 37/3426
USPC 204/298.13

(57) ABSTRACT

Provided is a sputtering target which comprises a metal matrix phase comprising Co and Pt, Co and Cr, or Co, Cr and Pt; and an oxide phase at least containing Cr₂O₃, wherein Cr₂O₃ is contained in amount of 1 to 16 mol %. The sputtering target is characterized in that the total amount of alkali metals as impurities is 30 wt ppm or less. It becomes possible to inhibit the formation of spots originating from these impurities and detachment of magnetic thin films during or after film formation by sputtering. Accordingly, the magnetic thin film of a magnetic recording medium can be produced which has excellent durability.

### TECHNICAL FIELD

The present invention relates to a ferromagnetic material sputtering target that is used for forming a magnetic material thin film of a magnetic recording medium, in particular, a magnetic recording layer of a magnetic recording medium in a hard disk drive (HDD) employing a perpendicular magnetic recording system.

### BACKGROUND

In the field of magnetic recording represented by hard disk drives, ferromagnetic metal materials, i.e., Co, Fe, or Ni-based materials are used as materials for magnetic thin films that perform recording. Many of these magnetic thin films of magnetic recording media are produced by sputtering of ferromagnetic material sputtering targets of the above-mentioned materials because of high productivity.

As methods of producing these ferromagnetic material sputtering targets, a melting method and a powder metallurgy method are proposed. Which method is used for producing a target is determined depending on the required characteristics. Recently, the magnetic recording system has been converted from the longitudinal direction system to the perpendicular direction system, and the sputtering target used for forming a recording layer has been converted from a molten product to a sintered product of powder mixtures of a metal powder and an oxide powder.

Regarding the ferromagnetic material sputtering target produced by the powder metallurgy method, various technologies are known. For example, Patent Literature 1 discloses a method of producing a sputtering target by mixing a CoCr alloy powder, a Pt powder, a Co powder, a SiO₂ powder, and a Cr₂O₃ powder; sintering the resulting powder mixture in a die; and machining the resulting sintered compact. Such a method is also described in, for example, Patent Literatures 2 and 3.

### CITATION LIST

### Patent Literature

Patent Literature 1: Japanese Patent Laid-Open No. 2009-215617

Patent Literature 2: Japanese Patent Laid-Open No. 2007-31808

Patent Literature 3: Japanese Patent No. 4837801

### SUMMARY OF INVENTION

### Technical Problem

In some of oxide powders as raw materials of ferromagnetic material sputtering targets, for example, Cr₂O₃ powders produced by coprecipitation contain relatively large amounts of alkali metals and alkaline earth metals as impurities. In a Cr₂O₃ powder that is industrially used, several hundred weight parts per million of alkali metals and alkaline earth metals are contained. Consequently, when the raw material is directly used, alkali metals and alkaline earth metals may remain in the sputtering target.

If a sputtering target contains a large amount of impurities such as alkali metals, these impurities are oxidized during or after film formation by sputtering to form spots, resulting in a risk of preventing reading/writing of information on an information recording surface from being normally performed in some cases. In addition, after film formation by sputtering, these impurities are oxidized to cause detachment of the magnetic material thin film in some cases. These problems reduce the durability of the magnetic recording layer of a magnetic recording medium in some cases.

### Solution to Problem

In order to solve the above-mentioned problems, the present inventors have diligently studied and, as a result, have found that the durability of a magnetic recording layer of a magnetic recording medium can be improved by reducing the amount of impurities, i.e., alkali metals and alkaline earth metals, in a Cr₂O₃ powder.

Based on these findings, the present invention provides:
1) A sputtering target comprising a metal matrix phase comprising Co and Pt; or Co and Cr; or Co, Cr and Pt; and an oxide phase at least containing Cr₂O₃; Cr₂O₃ being contained in an amount of 1 to 16 mol %; and the total amount of alkali metals as impurities being 30 wt ppm or less.

The present invention also provides:
2) The sputtering target according to 1) above, wherein the amount of Na as an impurity is 10 wt ppm or less.

The present invention also provides:
3) The sputtering target according to 1) or 2) above, wherein the amount of K as an impurity is 10 wt ppm or less.

The present invention also provides:
4) The sputtering target according to any one of 1) to 3) above, wherein the total amount of alkaline earth metals as impurities is 30 wt ppm or less.

The present invention also provides:
5) The sputtering target according to any one of 1) to 4) above, wherein the amount of Ca as an impurity is 10 wt ppm or less.

The present invention also provides:
6) The sputtering target according to any one of 1) to 5) above, wherein the oxide phase comprises Cr₂O₃ and an oxide of at least one element selected from B, Mg, Al, Si, Ti, Zr, Nb, Ta, Co, and Mn.

The present invention also provides:
7) The sputtering target according to any one of 1) to 6) above, wherein the metal matrix phase contains at least one element selected from B, Cu, Mo, Ru, Ta, and W.

### Effect of Invention

A ferromagnetic material sputtering target in which the contents of alkali metals and alkaline earth metals as impurities are reduced can inhibit formation of spots originating from these impurities and detachment of magnetic thin films during or after film formation by sputtering. Therefore, such a ferromagnetic material sputtering target has an advantage of being capable of producing the magnetic thin film of a magnetic recording medium so as to have excellent durability. In addition, the number of defective magnetic recording films formed by sputtering is reduced to provide advantages of improving the yield and reducing the cost.

### DETAILED DESCRIPTION

The ferromagnetic material sputtering target of the present invention has a structure including a metal matrix phase comprising Co—Pt, or Co—Cr, or Co—Cr—Pt and an oxide phase composed of nonmagnetic particles finely dispersed in the metal matrix phase. The metal matrix phase of the ferromagnetic material sputtering target may have any composition that gives characteristics as a magnetic material thin film for a magnetic recording medium.

Examples of the composition of the metal matrix phase include a Co—Pt metal matrix phase composed of 5 mol % or more and 30 mol % or less of Pt and the remainder being Co, a Co—Cr metal matrix phase composed of 5 mol % or more and 20 mol % or less of Cr and the remainder being Co, and a Co—Cr—Pt metal matrix phase composed of 20 mol % or less but higher than 0 mol % of Cr, 5 mol % or more and 30 mol % or less of Pt, and the remainder being Co.

In the ferromagnetic material sputtering target of the present invention, the majority of the oxide phase consisting of nonmagnetic particles contains 1 to 16 mol % of Cr₂O₃. The Cr₂O₃ powder produced by coprecipitation for industrial use contains relatively large amounts of impurities such as alkali metals and alkaline earth metals. Accordingly, the contents of alkali metals and alkaline earth metals contained in the sputtering target of the present invention as impurities can be controlled by appropriately treating such Cr₂O₃.

In the ferromagnetic material sputtering target of the present invention, the total amount of alkali metals as impurities is 30 wt ppm or less. Since alkali metals are apt to be oxidized, a content thereof of higher than 30 wt ppm tends to form spots on the magnetic material thin film of an information recording surface, which may prevent reading/writing of information from being normally performed. In addition, after film formation by sputtering, these alkali metals are oxidized to cause detachment of the sputtered film in some cases.

Among the alkali metals, sodium (Na) and potassium (K) particularly cause problems as impurities. Thus, the sodium content needs to be controlled to be 10 wt ppm or less, more preferably, 1 wt ppm or less. In addition, the potassium content is controlled to be 10 wt ppm or less, more preferably, 1 wt ppm or less.

In the ferromagnetic material sputtering target of the present invention, the total amount of alkaline earth metals as impurities is 30 wt ppm or less. Since alkaline earth metals are also apt to be oxidized similarly to alkali metals, if the content thereof is higher than 30 wt ppm, spots may be formed on the magnetic material thin film of an information recording surface to prevent reading/writing of information from being normally performed. In addition, after film formation by sputtering, these alkaline earth metals are oxidized to cause detachment of the sputtered film in some cases.

Among the alkaline earth metals, calcium (Ca) particularly causes problems as an impurity. Thus, the calcium content needs to be controlled to be 10 wt ppm or less, more preferably, 1 wt ppm or less.

In the ferromagnetic material sputtering target of the present invention, the oxide phase contains an oxide of at least one element selected from B, Mg, Al, Si, Ti, Zr, Nb, Ta, Co, and Mn, in addition to Cr₂O₃. The nonmagnetic oxide phase of the ferromagnetic material sputtering target may have any composition that gives characteristics as a magnetic material thin film for a magnetic recording medium.

In the ferromagnetic material sputtering target of the present invention, the metal matrix phase can further contain at least one element selected from B, Cu, Mo, Ru, Ta, and W. The amount of the element or elements can be appropriately controlled to give the characteristics as a magnetic material thin film for a magnetic recording medium.

The ferromagnetic material sputtering target in which the contents of alkali metals and alkaline earth metals are reduced can inhibit formation of spots originating from these impurities and detachment of magnetic material thin films due to oxidation during or after film formation by sputtering. Hence, the ferromagnetic material sputtering target has an advantage of being able to produce the magnetic thin film of a magnetic recording medium which has excellent durability. In addition, the number of defective magnetic recording films formed by sputtering is reduced to provide advantages of improving the yield and reducing the cost.

The ferromagnetic material sputtering target of the present invention can be produced by the following process, for example.

A Cr₂O₃ raw material powder is prepared, and this raw material powder is washed with stirring in pure water. On this occasion, the pure water is warmed to a temperature of 40° C. or more. A temperature of lower than 40° C. provides an insufficient washing effect.

In addition, on this occasion, the volume of the pure water is 50 L or more based on 1 kg of a Cr₂O₃ raw material powder, when the total amount of alkali metal and alkaline earth metal impurities in the Cr₂O₃ raw material powder is about 1000 wt ppm. A volume of less than 50 L provides an insufficient washing effect.

Subsequently, the washing solution is filtered and dried to give a Cr₂O₃ powder in which the amounts of alkali metal and alkaline earth metal impurities are significantly reduced.

Subsequently, metal powders, i.e., a Co raw material powder, a Cr raw material powder, and a Pt raw material powder, are prepared, and oxide powders, i.e., a TiO₂ raw material powder, a SiO₂ raw material powder, and a Cr₂O₃ powder produced by the above-described process are weighed to give a predetermined target composition. On this occasion, each raw material powder preferably has a controlled average particle diameter.

These powders are charged and sealed in a ball mill pot together with zirconia balls as a pulverizing medium and are pulverized and mixed. As the mixer, for example, a ball mill, a mixer, or a mortar can be used, but it is desirable to use a strong mixing means such as a ball mill for efficiently performing uniform refinement. In addition, in light of oxidation during mixing, the mixing is preferably performed in an inert gas atmosphere or in vacuum.

The obtained powder mixture is packed in a carbon mold and is sintered with a vacuum hot-pressing apparatus into a sintered compact. The molding and sintering are not limited to hot pressing and can also be performed by sintering with discharge plasma or hot isostatic pressing treatment. The retention temperature for the sintering is preferably set to the lowest temperature within the temperature range in which the target is sufficiently densified. Though it varies depending on the composition of a target, in many cases, the temperature is in a range of 800° C. to 1200° C. Crystal growth of the sintered compact can be inhibited by performing the sintering at a lower temperature. The pressure during the sintering is preferably 20 to 40 MPa.

The ferromagnetic material sputtering target of the present invention can be produced by machining the obtained sintered compact into a desired shape.

### EXAMPLES

The present invention will now be described by examples and comparative examples. The examples are merely exemplary and are not intended to limit the present invention. That is, the present invention is limited only by the claims and encompasses various modifications in addition to the examples included in the present invention.

### Example 1

One kilogram of a Cr₂O₃ raw material powder having a purity of 99.9% was prepared and was washed with stirring in 50 L of pure water having a temperature of 50° C. for 1 hour, followed by filtration and drying. The analytical values of impurities before and after the washing with pure water are shown in Table 1. The amounts of impurities in the raw material powder after washing with pure water were as follows: Na: 15 wt ppm, K: <1 wt ppm, and Ca: 1 wt ppm.

Subsequently, a Co powder having an average particle diameter of 3 μm, a Cr powder having an average particle diameter of 5 μm, a Pt powder having an average particle diameter of 3 μm, a TiO₂ powder having an average particle diameter of 1 μm, a SiO₂ powder having an average particle diameter of 1 μm, and a Cr₂O₃ powder having an average particle diameter of 3 μm prepared by removing impurities such as sodium by the procedure shown in Table 1 were prepared.

These powders were weighed at weight ratios of Co powder: 41.22 wt %, Cr powder: 9.41 wt %, Pt powder: 35.29 wt %, TiO₂ powder: 3.85 wt %, SiO₂ powder: 2.90 wt %, and Cr₂O₃ powder: 7.33 wt % to give a target composition of 58Co—15Cr—15Pt—4TiO₂—4SiO₂—4Cr₂O₃ (mol %).

Subsequently, the Co powder, the Cr powder, the Pt powder, the TiO₂ powder, the SiO₂ powder, and the Cr₂O₃ powder were charged into a 10-L ball mill pot together with zirconia balls as a pulverizing medium, and the ball mill pot was sealed and rotated for 20 hours for mixing. The resulting powder mixture was loaded in a carbon mold and was hot-pressed in a vacuum atmosphere under conditions of a temperature of 1050° C., a retention time of 2 hours, and a pressure of 30 MPa to give a sintered compact. The sintered compact was ground with a grinder into a disk-shaped target having a diameter of 180 mm and a thickness of 5 mm.

As shown in Table 2, the amounts of main impurities in the sputtering target were as follows: Na: 1 wt ppm, K: <1 wt ppm, and Ca: 1 wt ppm. The amounts of impurities in the target prepared using the Cr₂O₃ powder washed with pure water as a raw material powder were all within the ranges of the present invention, i.e., Na: 10 wt ppm or less, K: 10 wt ppm or less, and Ca: 10 wt ppm or less. Incidentally, the amounts of other alkali metals and alkaline earth metals were very low such that the analysis thereof was difficult.

TABLE 1

| | Cr₂O₃ raw material powder (before washing) | | | | | After washing | | |
|---|---|---|---|---|---|---|---|---|
| | Purity | Na | K | Ca | Conditions | Na | K | Ca |
| | (%) | (wt ppm) | (wt ppm) | (wt ppm) | for washing | (wt ppm) | (wt ppm) | (wt ppm) |
| Example 1 | 99.9 | 300 | 110 | 150 | 50° C., pure water 50 L, 1 hr | 15 | <1 | 1 |
| Example 2 | 99.9 | 700 | 60 | 30 | 60° C., pure water 50 L, 1 hr | 12 | <1 | 1 |
| Example 3 | 99.9 | 300 | 110 | 150 | 50° C., pure water 50 L, 1 hr | 15 | <1 | 1 |
| Comparative | 99.9 | 300 | 110 | 150 | — | — | — | — |
| Example 1 | | | | | | | | |
| Comparative | 99.9 | 300 | 110 | 150 | 20° C., pure water 50 L, 1 hr | 180 | 80 | 120 |
| Example 2 | | | | | | | | |
| Comparative | 99.9 | 700 | 60 | 30 | — | — | — | — |
| Example 3 | | | | | | | | |
| Reference | 99.9 | 300 | 110 | 150 | — | — | — | — |
| Example 4 | | | | | | | | |

TABLE 2

| | | Na | K | Ca |
|---|---|---|---|---|
| | Blending composition (mol %) | (wtppm) | (wtppm) | (wtppm) |
| Example 1 | 58Co—15Cr—15Pt—4TiO₂—4SiO₂—4Cr₂O₃ | 1 | <1 | 1 |
| Example 2 | 59Co—15Cr—15Pt—1Ta₅O₂—6SiO₂—1Cr₂O₃—3C_{oO} | <1 | <1 | <1 |
| Example 3 | 49Co—15Cr—15Pt—5Ru—16Cr₂O₃ | 4 | 2 | 3 |
| Comparative | 58Co—15Cr—15Pt—4TiO₂—4SiO₂—4Cr₂O₃ | 22 | 15 | 17 |
| Example 1 | | | | |
| Comparative | 58Co—15Cr—15Pt—4TiO₂—4SiO₂—4Cr₂O₃ | 13 | 11 | 12 |
| Example 2 | | | | |
| Comparative | 59Co—15Cr—15Pt—1Ta₅O₂—6SiO₂—1Cr₂O₃—3C_{oO} | 11 | 10 | 12 |
| Example 3 | | | | |
| Reference | 58Co—15Cr—15Pt—4TiO₂—4SiO₂—0.5Cr₂O₃ | 4 | <1 | <1 |
| Example 4 | | | | |

### Comparative Example 1

A Cr₂O₃ raw material powder used as in Example 1 having a purity of 99.9% was prepared. The analytical values of impurities in the powder are shown in Table 1. The amounts of main impurities in the raw material powder were as follows: Na: 300 wt ppm, K: 110 wt ppm, and Ca: 150 wt ppm.

In Comparative Example 1, a sputtering target was produced directly using the Cr₂O₃ raw material powder without performing washing with pure water. The sputtering target was produced so as to have the same composition as that in Example 1 by the method as in Example 1 except the Cr₂O₃ powder.

As shown in Table 2, the main impurities in the sputtering target were as follows: Na: 22 wt ppm, K: 15 wt ppm, and Ca: 17 wt ppm. As shown above, the amounts of impurities in the target produced using the Cr₂O₃ powder not washed with pure water as a raw material powder were out of the ranges of the present invention.

### Comparative Example 2

A Cr₂O₃ raw material powder used as in Example 1 having a purity of 99.9% was prepared. In Comparative Example 2, the powder was washed with stirring in 50 L of pure water having a temperature of 20° C. for 1 hour, followed by filtration and drying. The analytical values of impurities before and after the washing with pure water are shown in Table 1. The amounts of impurities in the raw material powder after washing with pure water were as follows: Na: 180 wt ppm, K: 80 wt ppm, and Ca: 120 wt ppm.

A sputtering target was produced using this Cr₂O₃ powder washed with pure water. The sputtering target was produced so as to have the same composition as that in Example 1 by the same method as in Example 1 except the Cr₂O₃ powder.

As shown in Table 2, the main impurities in the sputtering target were as follows: Na: 13 wt ppm, K: 11 wt ppm, and Ca: 12 wt ppm. As shown above, the amounts of impurities in the target produced using the Cr₂O₃ powder washed with pure water at a low temperature as a raw material powder were out of the ranges of the present invention.

### Example 2

One kilogram of a Cr₂O₃ raw material powder having a purity of 99.9% was prepared and was washed with stirring in 50 L of pure water having a temperature of 60° C. for 1 hour, followed by filtration and drying. The analytical values of impurities before and after the washing with pure water are shown in Table 1. The amounts of impurities in the raw material powder after washing with pure water were as follows: Na: 12 wt ppm, K: <1 wt ppm, and Ca: 1 wt ppm.

This Cr₂O₃ raw material powder washed with pure water and each powder were weighed so as to give a target composition of 59Co—15Cr—15Pt—1Ta₅O₂—6SiO₂—1Cr₂O₃—3CoO (mol %), and a sputtering target was produced by the same method as in Example 1.

As shown in Table 2, the amounts of main impurities in the sputtering target were as follows: Na: <1 wt ppm, K: <1 wt ppm, and Ca: <1 wt ppm. The amounts of impurities in the target prepared using the Cr₂O₃ powder washed with pure water as a raw material powder were all within the ranges of the present invention, i.e., Na: 10 wt ppm or less, K: 10 wt ppm or less, and Ca: 10 wt ppm or less. Incidentally, the amounts of other alkali metals and alkaline earth metals were very low such that the analysis thereof was difficult.

### Comparative Example 3

A Cr₂O₃ raw material powder used as in Example 2 having a purity of 99.9% was prepared. The analytical values of impurities in the powder are shown in Table 1. The amounts of main impurities in the raw material powder were as follows: Na: 700 wt ppm, K: 60 wt ppm, and Ca: 30 wt ppm.

In Comparative Example 3, a sputtering target was produced directly using the Cr₂O₃ raw material powder without performing washing with pure water. The sputtering target was produced so as to have the same composition as that in Example 2 by the same method as in Example 2 except the Cr₂O₃ powder.

As shown in Table 2, the main impurities in the sputtering target were as follows: Na: 11 wt ppm, K: 10 wt ppm, and Ca: 12 wt ppm. As shown above, the amounts of impurities in the target produced using the Cr₂O₃ powder not washed with pure water as a raw material powder were out of the ranges of the present invention.

### Example 3

Cr₂O₃ raw material powder used as in Example 1 washed with pure water and each powder were weighed so as to give a target composition of 49Co—15Cr—15Pt—5Ru—16Cr₂O₃ (mol %), and a sputtering target was produced by the method as in Example 1.

As shown in Table 2, the amounts of main impurities in the sputtering target were as follows: Na: 4 wt ppm, K: 2 wt ppm, and Ca: 3 wt ppm. The amounts of impurities in the target prepared using the Cr₂O₃ powder washed with pure water as a raw material powder were all within the ranges of the present invention, i.e., Na: 10 wt ppm or less, K: 10 wt ppm or less, and Ca: 10 wt ppm or less. Incidentally, the amounts of other alkali metals and alkaline earth metals were very low such that the analysis thereof was difficult.

### Reference Example 4

Cr₂O₃ raw material powder used as in Example 1 having a purity of 99.9% was prepared and was directly used without performing washing with pure water.

In Reference Example 4, the respective powders were weighed so as to give a composition of 58Co—15Cr—15Pt—4TiO₂—4SiO₂—0.5Cr₂O₃ (mol %), and a sputtering target was produced by the same method as in Example 1.

As shown in Table 2, the amounts of main impurities in the sputtering target were as follows: Na: 4 wt ppm, K: <1 wt ppm, and Ca: <1 wt ppm. As shown above, it was revealed that a low Cr₂O₃ content gives a target containing low amounts of alkali metals and alkaline earth metals even if the Cr₂O₃ raw material powder is not washed with pure water.

As shown in examples above, it was confirmed in all Examples 1 to 3 that the amounts of sodium, potassium, and calcium were particularly reduced. The target having reduced amounts of alkali metals and alkaline earth metals have an effect of highly increasing the durability of a perpendicular magnetic recording medium.

### INDUSTRIAL APPLICABILITY

The present invention can reduce the amounts of alkali metals and alkaline earth metals contained as impurities in a ferromagnetic material sputtering target.

Accordingly, formation of spots caused by oxidation of these impurities and detachment of magnetic material thin films during or after sputtering can be inhibited using the target of the present invention. Consequently, the quality of a film formed by sputtering can be significantly improved, and a magnetic material thin film can be produced with a low cost. The present invention is useful as a ferromagnetic material sputtering target used for forming the magnetic material thin film of a magnetic recording medium, in particular, the magnetic recording layer of a hard disk drive.

1. A sputtering target comprising:
a metal matrix phase comprising Co and Pt, Co and Cr, or Co, Cr and Pt;
an oxide phase at least containing Cr₂O₃;
Cr₂O₃ being contained in an amount of 1 to 16 mol %; and
the total amount of alkali metals as impurities being 30 wt ppm or less.

2. The sputtering target according to claim 1, wherein the amount of Na as an impurity is 10 wt ppm or less.

3. The sputtering target according to claim 2, wherein the amount of K as an impurity is 10 wt ppm or less.

4. The sputtering target according to claim 3, wherein the total amount of alkali earth metals as impurities is 30 wt ppm or less.

5. The sputtering target according to claim 4, wherein the amount of Ca as an impurity is 10 wt ppm or less.

6. The sputtering target according to claim 5, wherein the oxide phase comprises Cr₂O₃ and an oxide of at least one element selected from B, Mg, Al, Si, Ti, Zr, Nb, Ta, Co, and Mn.

7. The sputtering target according to claim 6, wherein the metal matrix phase contains at least one element selected from B, Cu, Mo, Ru, Ta, and W.

8. The sputtering target according to claim 1, wherein the amount of K as an impurity is 10 wt ppm or less.

9. The sputtering target according to claim 1, wherein the total amount of alkali earth metals as impurities is 30 wt ppm or less.

10. The sputtering target according to claim 1, wherein the amount of Ca as an impurity is 10 wt ppm or less.

11. The sputtering target according to claim 1, wherein the oxide phase comprises Cr₂O₃ and an oxide of at least one element selected from B, Mg, Al, Si, Ti, Zr, Nb, Ta, Co, and Mn.

12. The sputtering target according to claim 1, wherein the metal matrix phase contains at least one element selected from B, Cu, Mo, Ru, Ta, and W.
